(19) United States
(12) Patent Application Publication
(10) Pub. No.: US 2016/0260445 A1
(43) Pub. Date: Sep. 8, 2016

(54) Audio Loudness Adjustment

(71) Applicant: Adobe Systems Incorporated, San Jose, CA (US)

(72) Inventor: Sven Duwenhorst, Hamburg (DE)

(21) Appl. No.: 14/639,919

(22) Filed: Mar. 5, 2015

(51) Int. Cl. G10L 25/84; G06F 3/0484; H03G 3/32; G10L 21/12; G06F 3/16; G10L 21/0364

(52) U.S. Cl. CPC G10L 25/84; G06F 3/165; G10L 21/0364; H03G 3/32; G10L 21/12; G06F 3/04847

(57) ABSTRACT

Audio loudness adjustment techniques are described. In one or more implementations, primary and secondary sound data originating as part of an audio signal is adjusted. For example, a loudness of the sound data is adjusted. To do so, the loudness, which indicates a sound intensity of the primary and secondary sound data, is determined. Adjustments are then computed for at least a portion of the audio signal based on a target dynamic range parameter, which defines a desired difference between the loudness of the primary and secondary sound data respectively. Based on the computed adjustments, a variety of actions may be performed, such as applying the adjustments to the audio signal to generate an adjusted audio signal in which the primary and secondary sound data substantially have the desired loudness difference. Further, a preview of the adjusted audio signal may be updated in real-time for display in a user interface.

### BACKGROUND

One characteristic that humans perceive when hearing a sound (e.g., output of an audio recording) is its loudness. Generally speaking, loudness is the primary psychological correlate of physical intensity.

In audio recordings, the loudness of recorded content varies over time for a variety of different reasons. For example, audio recordings of meetings in which different participants speak can exhibit variations in loudness due to the speakers being located at different positions relative to audio recording equipment (e.g., microphones), behaving in a way that influences the audio properties of their voices (e.g., by turning their heads, changing position, etc.), and so forth.

Conventional techniques for adjusting audio signals enable users to manually adjust recorded content through post-processing techniques that involve tools such as compressors, limiters, and noise suppressors. Manual adjustment of recorded content can be time-consuming, however, and often knowledge about audio processing is essential using conventional techniques to obtain a desired result. Consequently, these conventional techniques keep many users from adjusting characteristics, such as loudness, of recorded content. With reference back to the example in which a meeting is recorded, it may be desirable to adjust a loudness of recorded speech relative to a loudness of background noise also recorded. Due to the time associated with manually adjusting the loudness, however, conventional techniques keep many users from adjusting audio recordings of meetings.

### SUMMARY

Audio loudness adjustment techniques are described. In one or more implementations, primary and secondary sound data that originates as part of an audio signal is adjusted. A loudness of the primary and secondary sound data is adjusted, for example. To do so, loudness of the audio signal is determined that indicates a sound intensity of the primary and secondary sound data. Adjustments to the loudness for at least a portion of the audio signal are computed based on a target dynamic range parameter, which defines a desired difference between the loudness of the primary and secondary sound data respectively.

Based on the computed adjustments, a variety of actions may be performed. For example, the computed adjustments are applied to the audio signal to generate an adjusted audio signal in which the primary and secondary sound data substantially have the desired difference in the loudness. In addition or alternately, a preview of the adjusted audio signal may be updated in real-time for display in a user interface. The user interface in which the preview is displayed includes a user interface element (e.g., a slider bar) that enables a user to adjust the target dynamic range parameter. As a result of an adjustment of the target dynamic range parameter via the user interface, the adjustments to the loudness are computed and the preview of the audio signal is updated for display.

This Summary introduces a selection of concepts in a simplified form that are further described below in the Detailed Description. As such, this Summary is not intended to identify essential features of the claimed subject matter, nor is it intended to be used as an aid in determining the scope of the claimed subject matter.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items. Entities represented in the figures may be indicative of one or more entities and thus reference may be made interchangeably to single or plural forms of the entities in the discussion.

FIG. 1 is an illustration of an environment in an example implementation that is operable to employ techniques described herein.

FIG. 2 illustrates an example user interface that includes a user interface element for adjusting a target dynamic range parameter and waveform representations configured to represent an unadulterated and adjusted version of an audio signal.

FIG. 3 illustrates the example user interface from FIG. 2, but in which the target dynamic range parameter has been adjusted and in which the waveform representation to preview adjustments made to the audio signal is updated.

FIG. 4 illustrates from the environment of FIG. 1 a computing device having a loudness adjustment module and other components to implement the techniques described herein in greater detail.

FIG. 5 is a flow diagram depicting a procedure in an example implementation in which loudness of an audio signal is adjusted based on a target dynamic range parameter that defines a desired difference between the loudness of primary and secondary sound data that originates as part of the audio signal.

FIG. 6 is a flow diagram depicting a procedure in an example implementation in which a user interface is generated that displays waveform representations of an unadulterated version of an audio signal and a preview of an adjusted version of the audio signal, and in which the preview of the adjusted version of the audio signal is updated based on input received to adjust a target dynamic range parameter.

FIG. 7 illustrates an example system including various components of an example device that can be employed for one or more implementations of audio loudness adjustment techniques described herein.

### DETAILED DESCRIPTION

Overview

Conventional techniques for adjusting audio signals (e.g., audio recordings) to obtain a desired result are time-consuming. Oftentimes, such techniques involve making manual adjustments to the audio signal with tools such as compressors, limiters, and noise suppressors. Making manual adjustments of this sort, to obtain the desired result in an efficient manner, involves knowledge of audio processing beyond that which is possessed by most users. Additionally, some simplistic techniques for adjusting audio signals result in adjusted audio signals having undesirable characteristics. For example, simplistic techniques for adjusting audio recordings having speech, can result in speech that sounds unrealistic, e.g., the speech of the adjusted audio recording loses the dynamic behavior of the speech that was actually recorded.

Audio loudness adjustment techniques are described. In one or more implementations, input is received to adjust primary and secondary sound data that originates as part of an audio signal. In particular, the input received is configured to adjust a target dynamic range parameter, which defines a desired difference in loudness between the primary and secondary sound data. Based on adjustment of the target dynamic range parameter, loudness of the primary and secondary sound data is adjusted.

Consider an example in which primary and secondary sound data correspond to speech and background noise respectively of an audio recording. Input received to increase the target dynamic range parameter for such an audio recording indicates that a user desires a greater difference between the loudness of the speech and the background noise. Using the techniques described herein, portions of the audio recording are adjusted so that the primary and secondary sound data have substantially the desired difference in loudness. To achieve this result, some portions of the audio recording are amplified (or attenuated) and some portions are leveled. Unlike conventional techniques that result in unrealistic sounds, however, these adjustments are made to preserve the dynamics of the primary sound data, e.g., to preserve speech dynamics.

In addition, a graphical user interface is displayed that includes a preview of the adjusted audio signal. The preview of the adjusted audio signal is updated in real-time to inform a user as to how adjustments to the target dynamic range parameter affect the audio signal. In one or more implementations, the preview corresponds to a waveform representation of the adjusted audio signal, and the user interface includes another waveform representation of an unadulterated version of the audio signal. Given the two waveform representations, a user is able to compare the adjusted audio signal to the unadulterated version of the audio signal. With regard to the user interface, in one or more implementations it is configured to have a single user interface element (e.g., a slider bar) that enables the user to adjust the target dynamic range parameter. This contrasts with conventional techniques, which involve interaction with multiple different user interface elements to make a variety of different audio adjustments to achieve the same results as the techniques described herein.

In the following discussion, an example environment is first described that is configured to employ the techniques described herein. Example implementation details and procedures are then described which are performable in the example environment as well as other environments. Consequently, performance of the example procedures is not limited to the example environment and the example environment is not limited to performance of the example procedures.

Example Environment

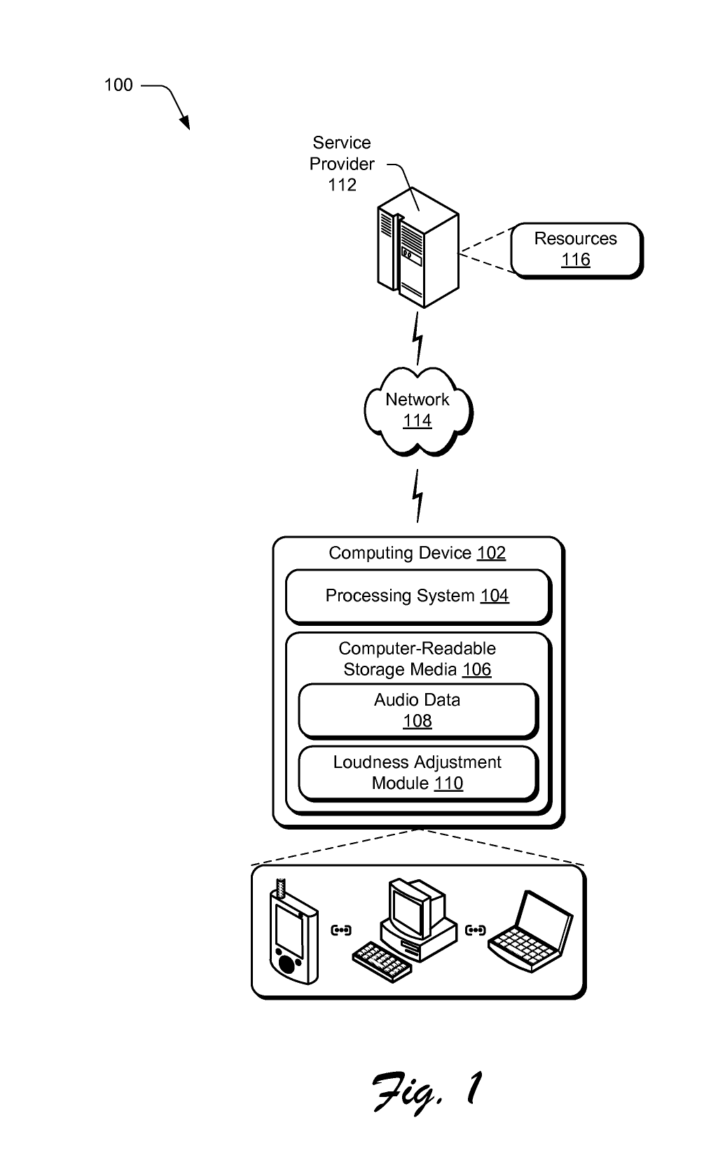

FIG. 1 is an illustration of an environment 100 in an example implementation that is operable to employ techniques described herein. The illustrated environment 100 includes a computing device 102 having a processing system 104 that includes one or more processing devices (e.g., processors) and one or more computer-readable storage media 106. The illustrated environment 100 also includes audio data 108 and a loudness adjustment module 110 embodied on the computer-readable storage media 106 and operable via the processing system 104 to implement corresponding functionality described herein. In at least some implementations, the computing device 102 includes functionality to access various kinds of web-based resources (content and services), interact with online providers, and so forth as described in further detail below.

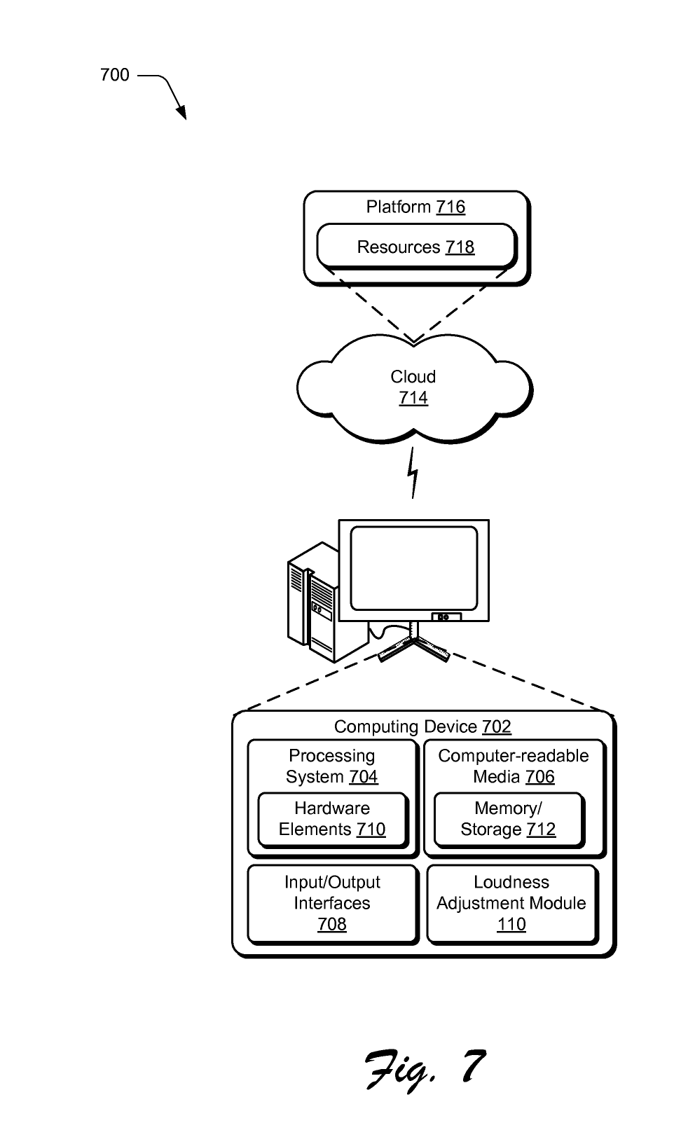

The computing device 102 is configurable as any suitable type of computing device. For example, the computing device 102 may be configured as a server, a desktop computer, a laptop computer, a mobile device (e.g., assuming a handheld configuration such as a tablet or mobile phone), a device configured to receive gesture input, a device configured to receive three-dimensional (3D) gestures as input, a device configured to receive speech input, a device configured to receive stylus-based input, a device configured to receive a combination of those inputs, and so forth. Thus, the computing device 102 may range from full resource devices with substantial memory and processor resources (e.g., servers, personal computers, game consoles) to a low-resource device with limited memory and/or processing resources (e.g., mobile devices). Additionally, although a single computing device 102 is shown, the computing device 102 may be representative of a plurality of different devices to perform operations “over the cloud” as further described in relation to FIG. 7.

The environment 100 further depicts one or more service providers 112, configured to communicate with computing device 102 over a network 114, such as the Internet, to provide a “cloud-based” computing environment. Generally speaking, service providers 112 are configured to make various resources 116 available over the network 114 to clients. In some scenarios, users may sign up for accounts that are employed to access corresponding resources from a provider. The provider may authenticate credentials of a user (e.g., username and password) before granting access to an account and corresponding resources 116. Other resources 116 may be made freely available, (e.g., without authentication or account-based access). The resources 116 can include any suitable combination of services and/or content typically made available over a network by one or more providers. Some examples of services include, but are not limited to, content creation services that offer audio processing applications (e.g., Sound Forge®, Creative Cloud®, and the like), online meeting services (e.g., Citrix GoToMeeting®, Skype®, Google Hangout®, and the like), online music providers (e.g., iTunes®, Amazon®, Beatport®, and the like) and so forth.

These services serve as sources for significant amounts of audio content. Such audio data may be formatted in any of a variety of audio formats, including but not limited to WAV, AIFF, AU, MP3, WMA, and so on. Audio data that is made available through these services may be recorded by or on behalf of users that have accounts with those services. For example, a user having an account with an online meeting service can schedule a meeting with multiple remote participants that each connect to the meeting using different connections. During the meeting, participants speak into audio recording equipment (e.g., a microphone) and their voices are output via audio output devices (e.g., speakers, headphones, etc.) of the other participants. In addition, many online meeting services allow users to record their meetings. When a user selects to record a meeting, the content spoken into the audio recording equipment during the meeting is recorded resulting in an audio recording of the meeting. The recording may then be played back or downloaded for a variety of purposes, including future playback and editing of the audio recording.

The loudness adjustment module 110 represents functionality to implement audio loudness adjustment techniques as described herein. For example, the loudness adjustment module 110 is configured in various ways to adjust primary and secondary sound data that originates as part of an audio signal based on a target dynamic range parameter. In general, a sound's “loudness” is the psychological correlate of physical intensity. The target dynamic range parameter defines a desired difference in loudness between the primary sound data (e.g., speech, classical music, and so on) and secondary sound data (e.g., background noise). Accordingly, the loudness adjustment module 110 is configured to adjust portions of the audio signal so that the primary sound data and the secondary sound data have approximately the desired difference in loudness. By way of example, the loudness adjustment module 110 may boost a portion of the primary sound data to match a level of other primary sound data, but leave portions of the secondary sound data unchanged.

In addition, the loudness adjustment module 110 represents functionality to generate a preview in real-time of an audio signal that is adjusted based on the target dynamic range parameter. In one or more implementations, the preview is included as part of a user interface that also includes a representation of an unadulterated version of the audio signal. The unadulterated version of the audio signal and the preview of the adjusted version may be displayed in the user interface as waveform representations, for instance. As is discussed in greater detail below the user interface is also configured with a single user interface element (e.g., a slider bar) that enables a user to adjust the target dynamic range parameter. The loudness adjustment module 110 is considered to generate the preview in real-time because as a user adjusts the user interface element to change the target dynamic range parameter the preview is updated to show corresponding adjustments to the audio signal. Consequently, a user can immediately see effects to the audio signal of adjusting the target dynamic range parameter. Thus, users without extensive audio processing knowledge can easily adjust audio recordings to obtain a desired result.

The loudness adjustment module 110 is implementable as a software module, a hardware device, or using a combination of software, hardware, firmware, fixed logic circuitry, etc. Further, the loudness adjustment module 110 is implementable as a standalone component of the computing device 102 as illustrated. In addition or alternatively, the loudness adjustment module 110 is configurable as a component of a web service, an application, an operating system of the computing device 102, a plug-in module, or other device application as further described in relation to FIG. 7.

Having considered an example environment, consider now a discussion of some example details of the techniques for audio loudness adjustment in accordance with one or more implementations.

Audio Loudness Adjustment Details

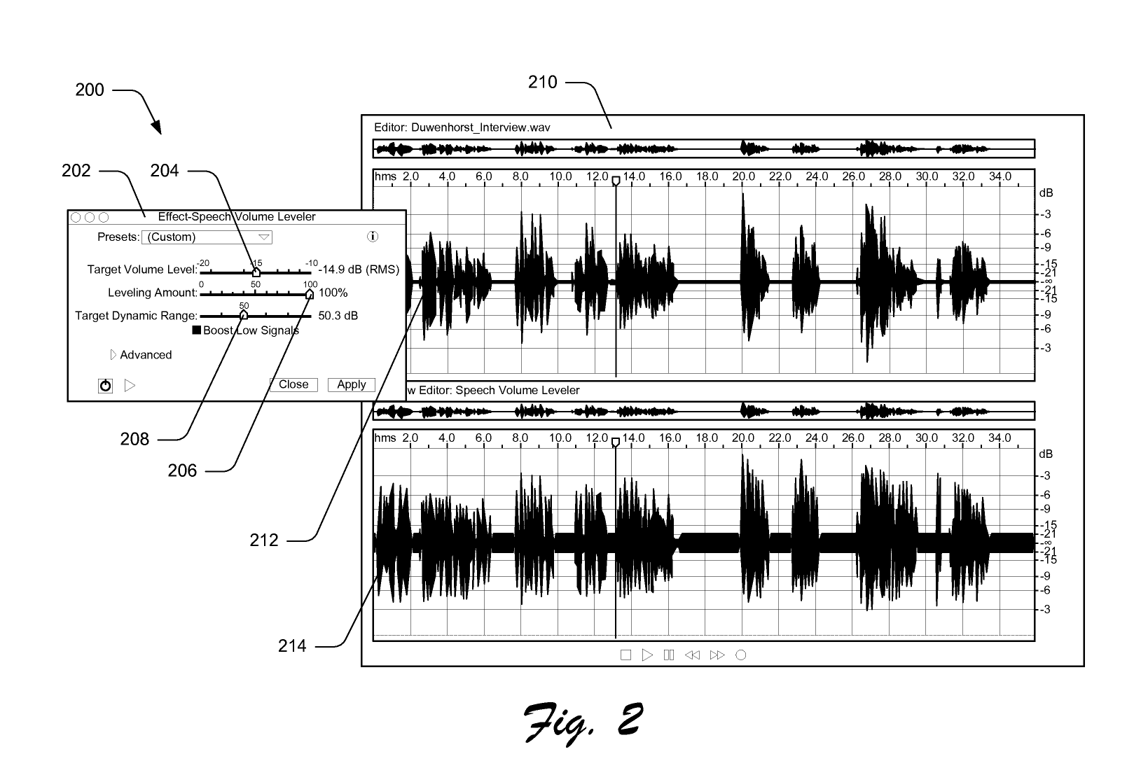

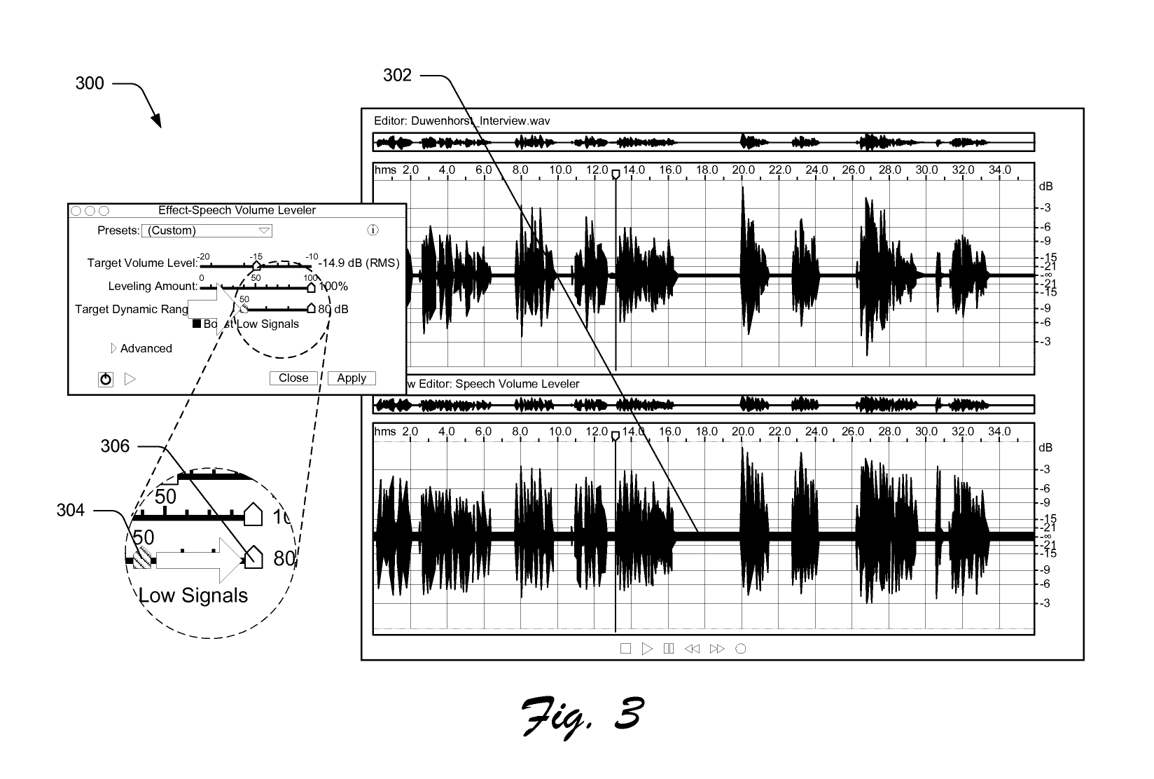

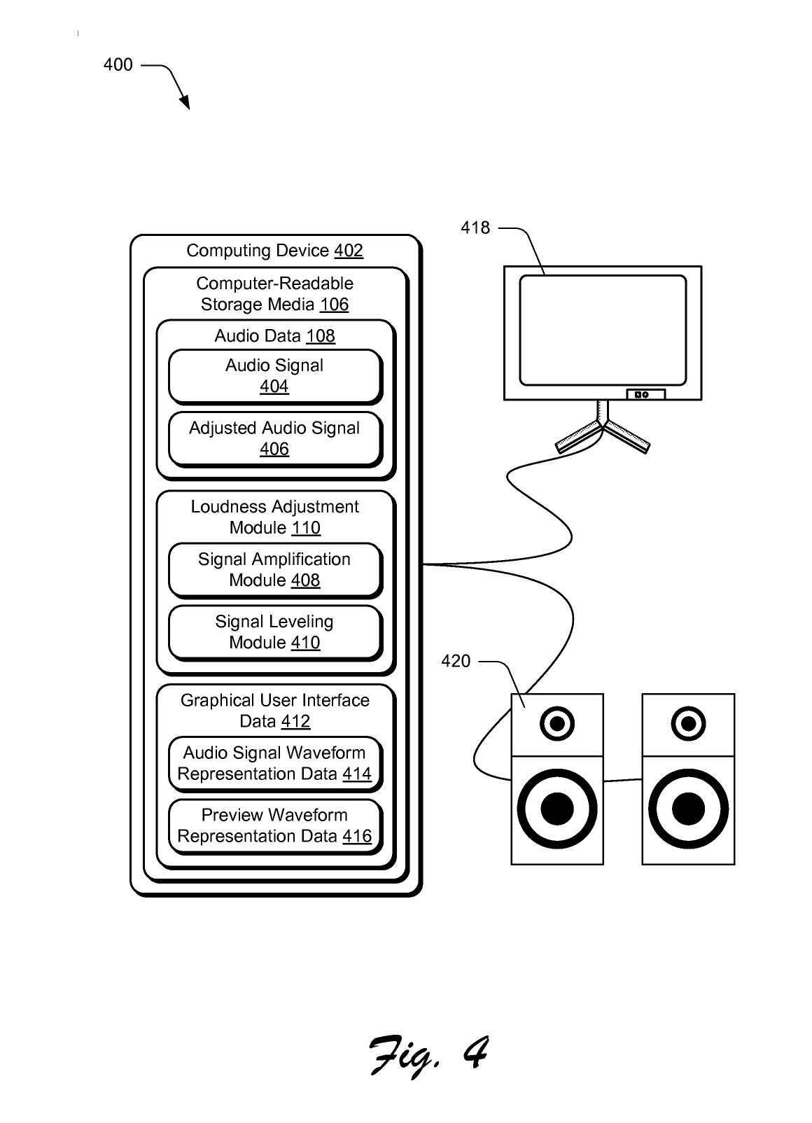

This section describes some example details of audio loudness adjustment techniques in accordance with one or more implementations. FIGS. 2 and 3 depict an example graphical user interface that is usable to implement audio loudness adjustment techniques. The example graphical user interface of FIGS. 2 and 3 also illustrates aspects pertinent to the discussion of the computing device included in FIG. 4.

FIG. 2 depicts an example user interface at 200 that includes a user interface element for adjusting the target dynamic range parameter, and waveform representations configured to represent an unadulterated and adjusted version of an audio signal. In FIG. 2, a volume leveler window 202 includes multiple different user interface elements that can be manipulated by a user to adjust different characteristics of an audio signal, and thus adjust the audio signal. In particular, the volume leveler window 202 includes a target-volume user interface element 204 (target-volume UI element 204), a leveling-amount user interface element 206 (leveling-amount UI element 206), and a target dynamic range user interface element 208 (target dynamic range UI element 208). Although these interface elements are depicted as slider bars, other types of user interface elements may be used without departing from the spirit or scope of the techniques described herein. By way of example and not limitations, the target-volume UI element 204, leveling-amount UI element 206, and target dynamic range UI element 208 may be implemented as drop downs that allow a user to select a value, a text field enabling a user to type in a value, and so forth. Further, these user interface elements may be implemented using any combination of user interface element types.

In any case, the target-volume UI element 204, the leveling-amount UI element 206, and the target dynamic range UI element 208 enable a user to provide input to adjust corresponding parameters. For example, the target-volume UI element 204, the leveling-amount UI element 206, and the target dynamic range UI element 208 correspond to a target volume parameter, a leveling amount parameter, and a target dynamic range parameter respectively.

With regard to the particular user interface implementation illustrated in FIG. 2, a user may provide input to slide the user interface elements represented. By sliding the user interface elements, the user indicates that a change is to be made to the corresponding parameter. For example, a user may slide the target dynamic range UI element 208 to change a value of a target dynamic range parameter. According to the changed value of the target dynamic range parameter, adjustments are computed for portions of the audio signal. In a similar manner, input by a user to move the target-volume UI element 204 and the leveling-amount UI element 206 result in changes to a target volume parameter and a leveling amount parameter. Accordingly, adjustments are also computed responsive to changed values of the target volume parameter and the adjusted leveling amount parameter.

In addition to the volume leveler window 202, FIG. 2 also includes a window 210 configured to display representations of an unadulterated version of an audio signal and an adjusted version of the audio signal. In one or more implementations, the representations displayed as part of the user interface are waveform representations of the audio signal and the adjusted audio signal. The user interface of FIG. 2 is depicted having a first waveform representation 212 that is configured to represent the unadulterated audio signal and a second waveform representation 214 that is configured to represent the adjusted version of the audio signal.

FIG. 2 illustrates a scenario in which the target volume parameter, the leveling amount parameter, and the target dynamic range parameter mentioned above are set to default values. These default values are configured to cause the audio signal to be adjusted according to default settings. Consequently, the second waveform representation 214 is depicted differently than the first waveform representation 212 in FIG. 2, e.g., because it reflects adjustments applied to the audio signal according to the default values of the target volume parameter, the leveling amount parameter, and the target dynamic range parameter. In other words, the peaks and valleys of the first waveform representation 212 are different from the peaks and valleys of the second waveform representation 214, and the depicted amplitude of the various portions are different. By way of example, the first and second waveform representations may be displayed in this way before any user-initiated adjustments are made to the audio signal.

When a user adjusts the target-volume UI element 204, the leveling-amount UI element 206, or the target dynamic range UI element 208, however, the second waveform representation 214 is updated to reflect adjustments to the audio signal. Consequently, the second waveform representation 214 changes from the way it is initially displayed after a user provides input to further adjust the audio signal. In one or more embodiments, the default settings may be applied when the user interface is initially displayed. As such, the first waveform representation 212 and the second waveform representation 214 may look different when initially displayed as in FIG. 2. However, this automatic application of a default level of loudness adjustment may be turned on or off with an associated user interface element. Thus, when the user interface element for the automatic adjustment is turned off, the first waveform representation 212 and the second waveform representation 214 look the same when initially displayed, e.g., the peaks and valleys match and the amplitude over the signal matches

FIG. 3 depicts at 300 the example user interface of FIG. 2, but in which the target dynamic range parameter has been adjusted by a user and in which a waveform representation is updated to preview adjustments made to the audio signal. As noted just above, the second waveform representation 214 looks different than the first waveform representation 212 when adjustments are made to the audio signal. In FIG. 3, for instance, the second waveform representation 214 is depicted differently than in FIG. 2, e.g., the second waveform representation 214 in FIG. 3 is depicted having secondary data portions, such as secondary data portion 302, with a lesser amplitude than in FIG. 2. These updates to the second waveform representation 214 result from changes made by a user to parameters (e.g., the target volume parameter, leveling amount parameter, and target dynamic range parameter) for adjusting the audio signal.

FIG. 3 depicts a scenario in which the target dynamic range UI element 208 has been slid (e.g., via user input) from an initial position 304, corresponding to 50.3 decibels, to a different position 306, corresponding to 80 decibels. As a result, the target dynamic range parameter is changed according to the input, and adjustments are computed for the audio signal based on the change to the target dynamic range parameter. The computed adjustments are reflected in the second waveform representation 214. With reference to the depicted examples in FIGS. 2 and 3, the valleys of the secondary data represented by second waveform representation in FIG. 3 are lower than the valleys of the secondary data represented by the second waveform representation in FIG. 2.

To this extent, the second waveform representation 214 acts as a preview for the adjusted audio signal. It allows a user to see how changes made to the parameters via the user interface elements affect the audio signal, e.g., by comparing the first waveform representation 212 to the second waveform representation 214. The second waveform representation 214 may also act as a preview of an adjusted audio signal insofar as it can be displayed without having to actually generate the adjusted audio signal. Instead, the adjustments computed for portions of the audio signal are sufficient for updating the second waveform representation 214 to preview the adjusted audio signal.

With regard to updating the second waveform representation 214, the second waveform representation 214 is considered to be updated “substantially in real-time.” By “substantially in real-time” it is meant that there is at least some delay (minimally perceptible to the human eye) between a time when a user changes a parameter via a user interface element and a time when the second waveform representation 214 is updated to reflect corresponding adjustments computed for the audio signal. Such a delay results, in part, from a time to compute the adjustments and refresh the display of the second waveform representation 214 accordingly. Moreover, the longer the audio signal, the more time it takes for the adjustments to be computed.

Although the user interface depicted in FIGS. 2 and 3 includes representations of both an unadulterated version of the audio signal (e.g., the first waveform representation 212) and an adjusted version of the audio signal (e.g., the second waveform representation 214), it should be appreciated that a user interface having a representation configured to indicate solely the adjusted version of the audio signal may be implemented without departing from the spirit or scope of the techniques described herein. Moreover, the user interface may be configured in other ways without departing from the spirit or scope of the techniques described herein. By way of example and not limitation, the first waveform representation 212 and the second waveform representation 214 may be displayed in a same portion of the user interface rather than separated as in FIGS. 2 and 3, such that one of the waveform representations is displayed in front of the other (e.g., layered), or having different colors.

In a scenario in which the waveform representations are layered, the user interface may include touch functionality that enables a touch input performed relative to the layered waveform representations to impact the target dynamic range parameter. For example, a two-fingered gesture performed relative to the layered waveform representations, in which the two fingers move apart from one another and away from an x-direction axis of the waveform representations, may cause the target dynamic range parameter to increase. In contrast, a two-fingered gesture performed relative to the layered waveform representations, in which the two fingers move closer to one another and closer to an x-direction axis of the waveform representations, may cause the target dynamic range parameter to decrease. Furthermore, the representations of the audio signal and the adjusted audio signal may not be waveform representations, but rather other representations indicative of the audio signal and the adjusted audio signal.

With regard to implementation, FIG. 4 depicts a computing device having components that are usable to generate the user interface described just above. FIG. 4 depicts generally at 400 some portions of the environment 100 of FIG. 1, but in greater detail. In particular, the computer-readable storage media 106 of a computing device is depicted in greater detail.

In FIG. 4, the computer-readable storage media 106 is illustrated as part of computing device 402 and includes the audio data 108 and the loudness adjustment module 110. The audio data 108 is illustrated with audio signal 404 and adjusted audio signal 406, which represent data indicative of an audio signal and an audio signal that is adjusted according to the techniques described herein, respectively. Both the audio signal 404 and the adjusted audio signal 406 include at least primary and secondary sound data originating therefrom. By way of example, primary sound data may correspond to speech while secondary sound data corresponds to background noise. The primary sound data may also correspond to classical music while the secondary sound data corresponds to background noise. The primary and secondary sound data may correspond to yet other sounds or noises without departing from the spirit or scope of the techniques described herein. Moreover, the techniques described herein are usable when the audio signal 404 and the adjusted audio signal 406 have more than just primary and secondary sound data originating therefrom. By way of example, the audio signal 404 and the adjusted audio signal 406 may also have tertiary data, quaternary data, and so on, that originates therefrom without departing from the spirit or scope of the techniques described herein.

The loudness adjustment module 110 is illustrated with the signal amplification module 408 and the signal leveling module 410. These modules represent functionality of the loudness adjustment module 110 and it should be appreciated that such functionality may be implemented using more or fewer modules than those illustrated. In general, the loudness adjustment module 110 may employ the signal amplification module 408 and the signal leveling module 410 to adjust portions of an audio signal based on adjustments computed using the target dynamic range parameter.

As discussed above, the target dynamic range parameter defines a desired difference between the loudness of the primary and secondary sound data that originates as part of the audio signal 404. As also discussed above, the “loudness” indicates a sound intensity of the primary and secondary sound data. In one or more implementations, the loudness corresponds to the root mean square (RMS) value of the sound data. An RMS value is a level value that is based on the intensity (e.g., energy) that is contained in the sound data. Although the RMS value of the sound data is discussed herein, it is to be appreciated that other measures indicative of the loudness may be used without departing from the spirit or scope of the techniques described herein. By way of example and not limitation loudness measurements such as Loudness Units Relative to Full Scale (LUFS) may be used.

The loudness adjustment module 110 represents functionality to determine a loudness of the audio signal 404 for a given portion thereof, e.g., by detecting the RMS value of the primary and secondary sound data of the audio signal 404. The loudness adjustment module 110 also represents functionality to determine a peak value and noise floor of the audio signal. A peak value is a maximum amplitude value for the audio signal 404 within a specified time, e.g., one period of an audio waveform of the audio signal 404. The noise floor corresponds to a minimum amplitude value of the audio signal 404 within the specified time.

Conventional techniques for processing the audio signal 404 involve feeding an audio signal that is to be adjusted (e.g., audio signal 404) into a delay line, which acts as a sliding window to estimate the loudness (e.g., RMS value) and the noise floor. The delay line causes the audio signal 404 to be divided into multiple smaller windows of defined length, e.g., multiple 50-millisecond windows. For a given number of the smaller windows (e.g., ten of the 50-millisecond windows), the RMS value is computed. Further, the RMS value is recomputed at a rate corresponding to the defined length, e.g., every 50 milliseconds given 50-millisecond windows. In this way, new samples of the audio signal 404 replace the old samples to maintain calculations for the given number of smaller windows. To this extent, the loudness adjustment module 110 may perform computations relative to a sliding window of 10 smaller 50-millisecond windows.

Each time the values are computed for the sliding window (e.g., every 50 milliseconds for the 500-millisecond sliding window), the loudness adjustment module 110 adds the corresponding RMS value to a list of RMS values. From the list, the loudness adjustment module 110 is configured to determine a value that represents the loudness of the current sliding window, e.g., for the current 500-millisecond portion of the audio signal 404. For example, the loudness adjustment module 110 may sort the list of values and select a value at seventy percent (70%) of the values of the smaller-windows as representative of the current 500-millisecond window's loudness. An averaged RMS value, determined as described, closely represents a shape of the waveform of the audio signal 404 in terms of loudness change and is robust against short time outliers.

To determine a noise floor of the audio signal 404, the loudness adjustment module 110 is configured to employ similar techniques. For example, the loudness adjustment module 110 computes an estimate of the noise floor for the given number of the smaller windows, e.g., ten of the 50-millisecond windows. The estimate of the noise floor gives an idea of the dynamic structure of the audio at a given time. Nonetheless, the estimate of the noise floor may also be recomputed at a rate corresponding to the defined length, e.g., every 50 milliseconds for 50-millisecond windows. Each time the values are estimated, the loudness adjustment module 110 compares the 50-millisecond window with the lowest RMS value to the current estimated noise floor value. If the lowest RMS value is lower than the current estimated noise floor value, then the lowest RMS value replaces the current noise floor value. If the lowest RMS value is not lower than the current noise floor value, then the loudness adjustment module 110 applies a decaying filter to the current noise floor value.

The loudness and the estimated noise floor that are computed by the loudness adjustment module 110 are used to control a compression characteristic for computing adjustments to the audio signal 404 that result in the adjusted audio signal 406. A depth of gain change adjustments, as well as a range allowed in the adjusted audio signal 406, are controlled by computation of a maxGain term, which is described in detail below. In contrast with conventional techniques for compressing audio signals, the techniques described herein adjust the compression characteristic for each sample (e.g., each time values are computed in conjunction with a new 50-millisecond window) according to an interpolation of the current measured peak, the loudness, and the noise floor. Interpolation of the current measured peak, the loudness, and the noise floor results in computation of the gain amplification that is allowed, which is represented by the maxGain term and is performed according to the following pseudocode:

```
if (inNoisefloor < kMinRMSNoiseFloor)
        inNoisefloor = kMinRMSNoiseFloor;
if (inNoisefloor > kMaxRMSNoiseFloor)
        inNoisefloor = kMaxRMSNoiseFloor;
if (peak < kPeakRangeMin)
        peak = kPeakRangeMin;
if (peak > kPeakRangeMax)
        peak = kPeakRangeMax;
gain = inLoudness + inReferenceLevel;
maxGain = kMaxGain + (((−inNoisefloor −
        kMaxGainDelta) × (kPeakRangeMax −
        inPeak)) / (kPeakRangeMax−kPeakRangeMin));
if (gain > maxGain)
        gain = maxGain;
```

The term inNoisefloor represents the noise floor that is estimated by the loudness adjustment module 110 for the current window, e.g., the current 500-millisecond window for which maxGain is being computed. The term peak represents the maximum amplitude value of the audio signal that is determined by the loudness adjustment module 110 for the current window.

Broadly speaking, a linear interpolation curve corresponding to the RMS values computed and that is placed over the observed audio signal as the RMS values are computed, would lag behind the observed audio signal. In other words, the computed loudness (e.g., the RMS values) would lag behind the perceived loudness (e.g., the audio signal). Accordingly, the signal is delayed by approximately the lag time so that the computed RMS values can catch up to the audio signal. The term inLoudness represents the linear interpolation between an RMS value of a smaller window under consideration and the RMS value of a next window that is to be considered. The term inReferenceLevel represents the target volume parameter that is adjustable using the target-volume UI element 204. In one or more implementations, the target volume parameter has an initial value that is defined by default settings but that can subsequently be changed through user manipulation of the target-volume UI element 204.

The terms kMaxGain, kMaxGainDelta, kPeakRangeMax, kPeakRangeMin, kMinRMSNoiseFloor, and kMaxRMSNoiseFloor are controlled by the target dynamic range parameter. The term kMaxGainDelta is linearly mapped, for example. When the target dynamic range parameter value is at its lowest allowable value (e.g., 30 dB) kMaxGainDelta is at its minimum value (e.g., 20 dB). In contrast, when the target dynamic range value is at its highest allowable value (e.g., 80 dB), kMaxGainDelta is increased (e.g., to 70 dB). Furthermore, when the leveling amount parameter is at zero, the kMaxGainDelta is configured to allow for a greater amount of signal dynamics, e.g., kMaxGainDelta may be 10 dB higher when the leveling amount parameter is zero than when it is at 100%. Thus, when a user provides input via the target dynamic range UI element 208 to change the target dynamic range parameter, the kMaxGain, kMaxGainDelta, kPeakRangeMax, kPeakRangeMin, kMinRMSNoiseFloor, and kMaxRMSNoiseFloor terms are changed accordingly.

In an example scenario, the term kMaxGain is set to ten decibels (10 dB), the term kPeakRangeMax is set to negative ten decibels (−10 dB), the term kPeakRangeMin is set to negative forty decibels (−40 dB), the term kMinRMSNoiseFloor is set to negative sixty decibels (−60 dB), and the term kMaxRMSNoiseFloor is set to negative fifty decibels (−50 dB). In this scenario, a user may specify (e.g., via the target dynamic range UI element 208) that the target dynamic range parameter is thirty decibels (30 dB), which results in higher amplification of the audio signal 404 than when the target dynamic range parameter is larger, e.g., sixty decibels. In addition, specification of thirty decibels for the target dynamic range parameter results in a value of twenty decibels (20 dB) for the term kMaxGainDelta in this scenario. Given these values, the maximum amount that the signal amplification module 408 is allowed to amplify the audio signal at the noise floor level is computed according to the maxGain equation as follows:

maxGain=kMaxGain+(((−inNoisefloor−kMaxGainDelta)×(kPeakRangeMax−inPeak))/(kPeakRangeMax−kPeakRangeMin))

maxGain=10+(((−(−50)−20)×(−10−(−40))/(−10−(−40)))

maxGain=40

Further, given these values, the maximum amount that the signal amplification module 408 is allowed to amplify the audio signal at the peak level is computed according to the maxGain equation as follows:

maxGain=kMaxGain+(((−inNoisefloor−kMaxGainDelta)×(kPeakRangeMax−inPeak))/(kPeakRangeMax−kPeakRangeMin))

maxGain=10+(((−(−50)−20)×(−10−(−10))/(−10−(−40)))

maxGain=10

Consequently, low level portions of the audio signal (e.g., those at or near the noise floor) are boosted by a large amount (e.g., 40 dB), while high level portions of the audio signal (e.g., those at or near the peak) are boosted by a small amount, if at all (e.g., 0-1 dB). It should be noted that time also has an impact on amplification achieved as a result of the maxGain calculation. In general, maxGain, the peak, and the noise floor are subject to a simple time envelope that causes those parameters to be subject to attack and decay. To this extent, if a value for one of these parameters observed for a sample (e.g., a smaller 50-millisecond window) is larger than the last sample value, the resulting value computed becomes a function of both previously determined values and a value of a new sample value. By way of example, the new sample value may be derived from an exponential function. If, however, the value for one of these parameters observed for a sample is equal or less than the last sample value, a decay function is applied.

Given a scenario in which the current peak value is higher than the estimated noise floor, for example, a noise gate may be kept open and a counter reset to a maximum hold time in audio signal samples, e.g., the smaller 50-millisecond windows. A gain change may then be computed and converted to a linear gain. When the noise gate is open, the linear gain may be applied with a specified attack time (e.g., 10 milliseconds). Otherwise, the linear gain is applied with a specified release time (e.g., 1000 milliseconds). The values for attack and release times can be changed, for example according to user input, to provide particular results.

Alternately, the user may specify (e.g., via the target dynamic range UI element 208) that the target dynamic range parameter is sixty decibels (60 dB), which results in lower amplification of the audio signal 404 than when the target dynamic range parameter is lower, e.g., thirty decibels. In addition, specification of sixty decibels for the target dynamic range parameter results in a value of fifty decibels (50 dB) for the term kMaxGainDelta in this scenario. Given these values, the maximum amount that the signal amplification module 408 is allowed to amplify the audio signal at the noise floor level is computed according to the maxGain equation as follows:

maxGain=kMaxGain+(((−inNoisefloor−kMaxGainDelta)×(kPeakRangeMax−inPeak))/(kPeakRangeMax−kPeakRangeMin))

maxGain=10+(((−(−50)−50)×(−10−(−40))/(−10−(−40)))

maxGain=10

Taking the equation above, the value calculated for maxGain is positive ten. In any case, given the different value for the target dynamic range parameter (e.g., 60 dB), the maximum amount that the signal amplification module 408 is allowed to amplify the audio signal at the peak level is computed according to the maxGain equation as follows:

maxGain=kMaxGain+(((−inNoisefloor−kMaxGainDelta)×(kPeakRangeMax−inPeak))/(kPeakRangeMax−kPeakRangeMin))

maxGain=10+(((−(−50)−50)×(−10−(−10))/(−10−(−40)))

maxGain=10

As indicated above, these values for maxGain correspond to an amount of gain that the signal amplification module 408 is allowed to apply to the audio signal 404. In other words, when the target dynamic range parameter is set to thirty decibels, the signal amplification module 408 is configured to adjust portions of the audio signal 404 at the floor level by applying a gain of forty decibels. Further, the signal amplification module 408 is not to adjust portions of the audio signal 404 at the peak level, as indicated by the maxGain value of zero. When the target dynamic range parameter is instead set to sixty decibels, the signal amplification module 408 is configured to adjust portions of the audio signal at the floor level by applying a gain of ten decibels. Like the thirty-decibel example, the signal amplification module 408 is not to adjust portions of the audio signal 404 at the peak level, as indicated by the maxGain value of zero.

Adjustment computations, such as those discussed above, are performed by the loudness adjustment module 110. To apply the adjustments to the audio signal 404 (e.g., to result in the adjusted audio signal 406), the loudness adjustment module 110 employs the signal amplification module 408 and the signal leveling module 410. The signal amplification module 408 is configured to amplify or attenuate portions of the audio signal 404, e.g., portions of the primary or secondary sound data. When doing so, the signal amplification module 408 amplifies or attenuates the audio signal 404 according to the maxGain calculations. The signal leveling module 410 is configured to level portions of the audio signal 404. The signal leveling module 410 may do by leveling portions of the audio signal within the constraints of the maxGain calculations. By way of example, the signal leveling module 410 may level primary sound data so that it has a desired loudness and may level the secondary sound data so that it has a different desired loudness.

After the adjustments made by the signal amplification module 408 and the signal leveling module, the adjusted audio signal 406 may be processed by an optional compressor (not shown) that is configured using static settings. This compressor can be a broad-band or multi-band compressor.

The computer-readable storage media 106 also includes graphical user interface data 412, which is illustrated having audio signal waveform representation data 414 and preview waveform representation data 416. In general, the graphical user interface data 412 represents data that enables display of a user interface for implementing the audio loudness adjustment techniques described herein, e.g., the user interface depicted in FIGS. 2 and 3. For example, the graphical user interface data 412 enables an audio loudness adjustment user interface to be displayed via display device 418. The graphical user interface data 412 includes data that enables the volume leveler window 202, and the user interface elements thereof, to be displayed via the display device 418 and be selectable to specify input for the corresponding parameters.

The audio signal waveform representation data 414 represents data that enables a representation of the audio signal 404 to be displayed. With reference to FIGS. 2 and 3, the audio signal waveform representation data 414 enables the first waveform representation 212 to be displayed for the audio signal 404. In contrast, the preview waveform representation data 416 represents data that enables a preview of the adjusted audio signal 406 to be displayed. By preview, it is meant that a waveform representation may be displayed without actually generating the adjusted audio signal 406. In other words, the adjustment calculations may be performed by the loudness adjustment module 110 based on the target dynamic range parameter, and the preview waveform representation data 416 may simply reflect those calculated adjustments to the audio signal 404. In any case, the preview waveform representation data 416 enables the second waveform representation 214 to be displayed as a preview of the adjusted audio signal 406. It is to be appreciated that when the adjusted audio signal 406 has been generated (e.g., through application of the computed adjustments by the signal amplification module 408 and the signal leveling module 410), the preview waveform representation data 416 enables the second waveform representation 214 to be displayed for the adjusted audio signal 406.

FIG. 4 also includes audio output device(s) 420. The audio output device(s) 420 represent a variety of devices that are configured to output sound data. By way of example, and not limitation, the audio output device(s) 420 include on-board speakers of the computing device 402, speakers having a wired connection to the computing device 402, speakers that are wirelessly connected to the computing device 402, headphones that are plugged into the computing device 402 through a headphone jack, headphones that are wirelessly connected to the computing device 402, and so forth. The audio output devices(s) 420 are configured to output the audio signal 404, the adjusted audio signal 406, or portions thereof.

Having discussed example details of the techniques for audio loudness adjustment, consider now some example procedures to illustrate additional aspects of the techniques.

Example Procedures

This section describes example procedures for audio loudness adjustment in one or more implementations. Aspects of the procedures may be implemented in hardware, firmware, or software, or a combination thereof. The procedures are shown as a set of blocks that specify operations performed by one or more devices and are not necessarily limited to the orders shown for performing the operations by the respective blocks. In at least some implementations the procedures may be performed by a suitably configured device, such as example computing devices 102, 402 of FIGS. 1 and 4 that make use of a loudness adjustment module 110.

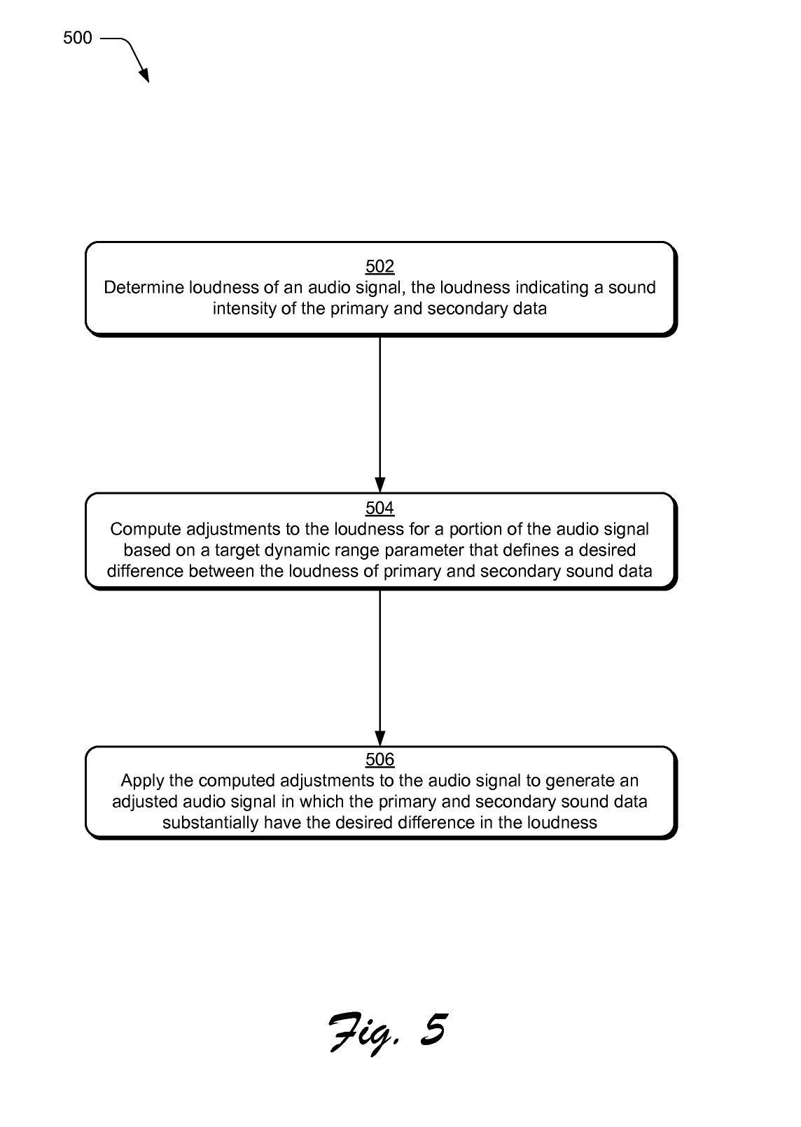

FIG. 5 depicts an example procedure 500 in which loudness of an audio signal is adjusted based on a target dynamic range parameter that defines a desired difference between the loudness of primary and secondary sound data that originates as part of the audio signal. Loudness of an audio signal is determined (block 502). The determined loudness is indicative of a sound intensity of primary and secondary data that originates as part of the audio signal. For example, the loudness adjustment module 110 determines loudness of the audio signal 404. As indicated above, the loudness adjustment module 110 may be configured to determine the loudness by computing an RMS value for portions of the audio signal, e.g., for 50-millisecond window of the audio signal. The loudness adjustment module 110 may do so for the entirety of the audio signal 404 or for a portion of the audio signal less than its entirety, e.g., a portion of the audio signal 404 that corresponds to a waveform representation displayed.

Based on a target dynamic range parameter that defines a desired difference between the loudness of the primary and secondary sound data respectively, adjustments are computed for at least a portion of the audio signal (block 504). For example, the loudness adjustment module 110 computes adjustments for at least a portion of the audio signal 404 based on the target dynamic range parameter. The adjustments are computed to cause loudness of the primary and secondary sound data to be different by approximately the desired amount. In particular, the computed adjustments are configured for adjusting portions of the audio signal 404 that correspond to the primary sound data so that a loudness of those portions lies within an allowable threshold of a desired loudness for the primary sound data. In a similar fashion, the computed adjustments are configured for adjusting portions of the audio signal that correspond to the secondary sound data so that a loudness of secondary-sound portions lies within an allowable threshold of a desired loudness for the secondary sound data. Furthermore, the loudness adjustment module 110 computes the adjustments with reference to the maxGain value as described in more detail above.

In one or more implementations, the computed adjustments are applied to the audio signal to generate an adjusted audio signal (block 506). In particular, the adjustments are made so that the primary and secondary sound data substantially have the desired difference in loudness. For example, the loudness adjustment module 110 employs the signal amplification module 408 to apply the adjustments calculated for portions of the audio signal at block 504. The signal amplification module 408 amplifies or attenuates portions of the audio signal 404 according to the calculated adjustments to generate the adjusted audio signal 406. The loudness adjustment module 110 also employs the signal leveling module 410 to apply calculated adjustments to portions of the audio signal, e.g., adjustments calculated at block 504. The signal leveling module 410 levels the audio signal 404 as part of the adjusting to result in the loudness of the primary and secondary sound data of the adjusted audio signal 406 being different by the desired amount, e.g., the desired difference that is defined via the target dynamic range parameter.

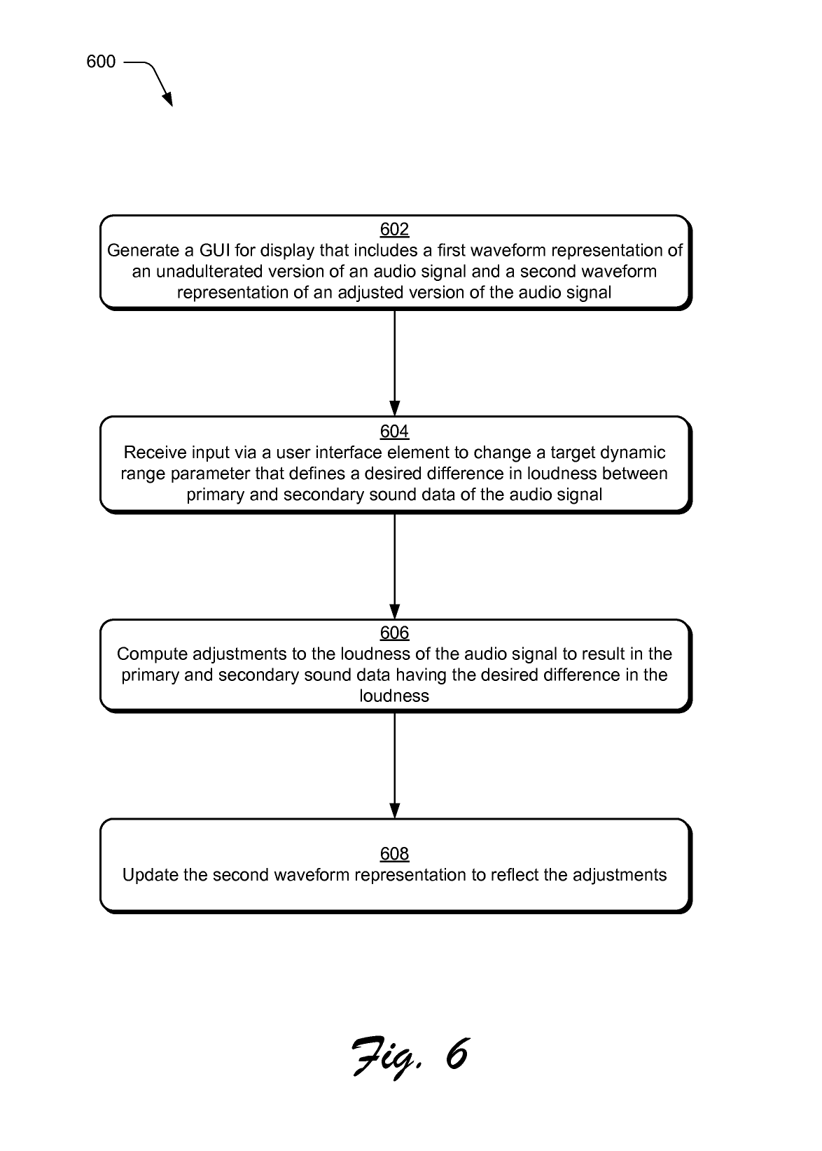

FIG. 6 depicts an example procedure 600 in which a user interface is generated that displays waveform representations of an unadulterated version of an audio signal and a preview of an adjusted version of the audio signal, and in which the preview of the adjusted version of the audio signal is updated based on input received to adjust a target dynamic range parameter. A graphical user interface is generated that includes a first waveform representation and a second waveform representation (block 602). The first waveform representation of the graphical user interface corresponds to an unadulterated version of an audio signal and the second waveform representation corresponds to a preview of an adjusted version of the audio signal.

For example, the computing device 402 generates a user interface, such as the user interface depicted in FIG. 2 that includes the first waveform representation 212 and the second waveform representation 214. To do so, the computing device 402 uses the graphical user interface data 412. In particular, the computing device 402 uses the audio signal waveform representation data 414, which is indicative of the audio signal 404, to generate the first waveform representation 212. The audio signal 404 is considered unadulterated insofar as it is the starting point for making loudness adjustments. To generate the second waveform representation 214, which previews the adjusted audio signal 406, the computing device 402 uses the preview waveform representation data 416. As discussed above, the second waveform representation 214 can be displayed to preview what the adjusted audio signal 406 will be like without actually generating the adjusted audio signal 406. If the adjusted audio signal 406 has been generated, however, then the second waveform representation 214 is indicative of the generated adjusted audio signal 406.

Input is received via a user interface element to change a target dynamic range parameter that defines a desired difference in loudness between primary and secondary sound data of the audio signal (block 604). For example, input is received via the target dynamic range UI element 208 to change a value of the target dynamic range parameter. With reference to FIGS. 2 and 3, the input is received via the target dynamic range UI element 208 to change a value of the target dynamic range parameter from 50.3 decibels as illustrated in FIG. 2 to 80 decibels as illustrated in FIG. 3. Such a change to the value of the target dynamic range parameter indicates that the user wishes to change the desired difference in loudness between the primary and secondary sound data.

Based on the change to the value of the target dynamic range parameter, adjustments to loudness are computed for portions of the audio signal (block 606). For example, the loudness adjustment module 110 computes adjustments to portions of the audio signal 404 based on the user input to change the value of the target dynamic range parameter from 50.3 decibels as illustrated in FIG. 2 to 80 decibels as illustrated in FIG. 3. As discussed with reference to block 504, adjustments are computed to cause the loudness of the primary and secondary sound data to be different by approximately the amount defined by the target dynamic range parameter.

The second waveform representation is updated in real-time to reflect the computed adjustments (block 608). For example, the second waveform representation 214 is updated to reflect the adjustments calculated at block 606. This updating of the second waveform representation 214 is represented in FIGS. 2 and 3, which illustrate the second waveform representation 214 in one way in FIG. 2 and in a different way in FIG. 3. The second waveform representation 214 of FIG. 3 reflects adjustments calculated relative to the audio signal 404 and based on the change to the target dynamic range parameter. In some scenarios the second waveform representation 214 is updated without generating the adjusted audio signal 406. Thus, the second waveform representation 214 acts as a preview that indicates how the changes will affect the audio signal 404 to result in the adjusted audio signal 406.

Further, the second waveform representation 214 is updated “substantially in real-time.” By “substantially in real-time” it is meant that there is at least some delay (minimally perceptible to the human eye) between a time when a user changes a parameter via a user interface element (e.g., at block 604) and a time when the second waveform representation 214 is updated to reflect corresponding adjustments computed for the audio signal. This minimal delay results from the time taken to perform the adjustment calculations, e.g., those computed at block 606.

In one or more implementations, a user interface element is displayed that allows a user to select to generate the adjusted audio signal 406. Accordingly, the adjustments that are previewed via the second waveform representation 214 are applied to the audio signal 404 to generate the adjusted audio signal 406. In other implementations, the adjusted audio signal 406 is generated automatically. In any case, once generated, the adjusted audio signal 406 can be output for playback over the audio output devices(s) 420. The audio signal 404 can also be output for playback over the audio output device(s) 420. In this way, a user may compare the audio signal 404 with the adjusted audio signal 406.

Having described example procedures in accordance with one or more implementations, consider now an example system and device that can be utilized to implement the various techniques described herein.

Example System and Device

FIG. 7 illustrates an example system generally at 700 that includes an example computing device 702 that is representative of one or more computing systems and/or devices that may implement the various techniques described herein. This is illustrated through inclusion of the loudness adjustment module 110, which operates as described above. The computing device 702 may be, for example, a server of a service provider, a device associated with a client (e.g., a client device), an on-chip system, and/or any other suitable computing device or computing system.

The example computing device 702 includes a processing system 704, one or more computer-readable media 706, and one or more I/O interfaces 708 that are communicatively coupled, one to another. Although not shown, the computing device 702 may further include a system bus or other data and command transfer system that couples the various components, one to another. A system bus can include any one or combination of different bus structures, such as a memory bus or memory controller, a peripheral bus, a universal serial bus, and/or a processor or local bus that utilizes any of a variety of bus architectures. A variety of other examples are also contemplated, such as control and data lines.

The processing system 704 is representative of functionality to perform one or more operations using hardware. Accordingly, the processing system 704 is illustrated as including hardware elements 710 that may be configured as processors, functional blocks, and so forth. This may include implementation in hardware as an application specific integrated circuit or other logic device formed using one or more semiconductors. The hardware elements 710 are not limited by the materials from which they are formed or the processing mechanisms employed therein. For example, processors may be comprised of semiconductor(s) and/or transistors (e.g., electronic integrated circuits (ICs)). In such a context, processor-executable instructions may be electronically-executable instructions.

The computer-readable storage media 706 is illustrated as including memory/storage 712. The memory/storage 712 represents memory/storage capacity associated with one or more computer-readable media. The memory/storage component 712 may include volatile media (such as random access memory (RAM)) and/or nonvolatile media (such as read only memory (ROM), Flash memory, optical disks, magnetic disks, and so forth). The memory/storage component 712 may include fixed media (e.g., RAM, ROM, a fixed hard drive, and so on) as well as removable media (e.g., Flash memory, a removable hard drive, an optical disc, and so forth). The computer-readable media 706 may be configured in a variety of other ways as further described below.

Input/output interface(s) 708 are representative of functionality to allow a user to enter commands and information to computing device 702, and also allow information to be presented to the user and/or other components or devices using various input/output devices. Examples of input devices include a keyboard, a cursor control device (e.g., a mouse), a microphone, a scanner, touch functionality (e.g., capacitive or other sensors that are configured to detect physical touch), a camera (e.g., which may employ visible or non-visible wavelengths such as infrared frequencies to recognize movement as gestures that do not involve touch), and so forth. Examples of output devices include a display device (e.g., a monitor or projector), speakers, a printer, a network card, tactile-response device, and so forth. Thus, the computing device 702 may be configured in a variety of ways as further described below to support user interaction.

Various techniques may be described herein in the general context of software, hardware elements, or program modules. Generally, such modules include routines, programs, objects, elements, components, data structures, and so forth that perform particular tasks or implement particular abstract data types. The terms “module,” “functionality,” and “component” as used herein generally represent software, firmware, hardware, or a combination thereof. The features of the techniques described herein are platform-independent, meaning that the techniques may be implemented on a variety of commercial computing platforms having a variety of processors.

An implementation of the described modules and techniques may be stored on or transmitted across some form of computer-readable media. The computer-readable media may include a variety of media that may be accessed by the computing device 702. By way of example, and not limitation, computer-readable media may include “computer-readable storage media” and “computer-readable signal media.”

“Computer-readable storage media” refers to media and/or devices that enable persistent and/or non-transitory storage of information in contrast to mere signal transmission, carrier waves, or signals per se. Thus, computer-readable storage media does not include signals per se or signal bearing media. The computer-readable storage media includes hardware such as volatile and non-volatile, removable and non-removable media and/or storage devices implemented in a method or technology suitable for storage of information such as computer readable instructions, data structures, program modules, logic elements/circuits, or other data. Examples of computer-readable storage media may include, but are not limited to, RAM, ROM, EEPROM, flash memory or other memory technology, CD-ROM, digital versatile disks (DVD) or other optical storage, hard disks, magnetic cassettes, magnetic tape, magnetic disk storage or other magnetic storage devices, or other storage device, tangible media, or article of manufacture suitable to store the desired information and which may be accessed by a computer.

“Computer-readable signal media” refers to a signal-bearing medium that is configured to transmit instructions to the hardware of the computing device 702, such as via a network. Signal media typically may embody computer readable instructions, data structures, program modules, or other data in a modulated data signal, such as carrier waves, data signals, or other transport mechanism. Signal media also include any information delivery media. The term “modulated data signal” means a signal that has one or more of its qualities set or changed in such a manner as to encode information in the signal. By way of example, and not limitation, communication media include wired media such as a wired network or direct-wired connection, and wireless media such as acoustic, RF, infrared, and other wireless media.

As previously described, hardware elements 710 and computer-readable media 706 are representative of modules, programmable device logic and/or fixed device logic implemented in a hardware form that may be employed in some implementations to implement at least some aspects of the techniques described herein, such as to perform one or more instructions. Hardware may include components of an integrated circuit or on-chip system, an application-specific integrated circuit (ASIC), a field-programmable gate array (FPGA), a complex programmable logic device (CPLD), and other implementations in silicon or other hardware. In this context, hardware may operate as a processing device that performs program tasks defined by instructions and/or logic embodied by the hardware as well as a hardware utilized to store instructions for execution, e.g., the computer-readable storage media described previously.

Combinations of the foregoing may also be employed to implement various techniques described herein. Accordingly, software, hardware, or executable modules may be implemented as one or more instructions and/or logic embodied on some form of computer-readable storage media and/or by one or more hardware elements 710. The computing device 702 may be configured to implement particular instructions and/or functions corresponding to the software and/or hardware modules. Accordingly, implementation of a module that is executable by the computing device 702 as software may be achieved at least partially in hardware, e.g., through use of computer-readable storage media and/or hardware elements 710 of the processing system 704. The instructions and/or functions may be executable/operable by one or more articles of manufacture (for example, one or more computing devices 702 and/or processing systems 704) to implement techniques, modules, and examples described herein.

The techniques described herein may be supported by various configurations of the computing device 702 and are not limited to the specific examples of the techniques described herein. This functionality may also be implemented all or in part through use of a distributed system, such as over a “cloud” 714 via a platform 716 as described below.

The cloud 714 includes and/or is representative of a platform 716 for resources 718. The platform 716 abstracts underlying functionality of hardware (e.g., servers) and software resources of the cloud 714. The resources 718 may include applications and/or data that can be utilized while computer processing is executed on servers that are remote from the computing device 702. Resources 718 can also include services provided over the Internet and/or through a subscriber network, such as a cellular or Wi-Fi network.

The platform 716 may abstract resources and functions to connect the computing device 702 with other computing devices. The platform 716 may also serve to abstract scaling of resources to provide a corresponding level of scale to encountered demand for the resources 718 that are implemented via the platform 716. Accordingly, in an interconnected device implementation, implementation of functionality described herein may be distributed throughout the system 700. For example, the functionality may be implemented in part on the computing device 702 as well as via the platform 716 that abstracts the functionality of the cloud 714.

Conclusion

Although the invention has been described in language specific to structural features and/or methodological acts, it is to be understood that the invention defined in the appended claims is not necessarily limited to the specific features or acts described. Rather, the specific features and acts are disclosed as example forms of implementing the claimed invention.

What is claimed is:

1. In a digital audio environment to adjust primary and secondary sound data originating as part of an audio signal by one or more computing devices, a method comprising:
determining loudness of the audio signal by the one or more computing devices, the loudness indicating a sound intensity of the primary and secondary sound data;
computing adjustments to the loudness by the one or more computing devices for at least a portion of the audio signal based on a target dynamic range parameter that defines a desired difference between the loudness of the primary and secondary sound data respectively; and
applying the computed adjustments by the one or more computing devices to the audio signal to generate an adjusted audio signal in which the primary and secondary sound data substantially have the desired difference in the loudness.

2. A method as described in claim 1, further comprising receiving an input to specify the target dynamic range parameter, the adjustments to the loudness being computed responsive to receiving the input.

3. A method as described in claim 2, wherein the input to specify the target dynamic range parameter is received via a single user interface element.

4. A method as described in claim 2, wherein the input is received via a user interface that includes waveform representations that represent the audio signal and a preview of the adjusted audio signal.

5. A method as described in claim 4, further comprising generating the user interface for display, including generating the waveform representation of the preview substantially in real-time, the waveform representation of the preview being updated as the input to specify the target dynamic range parameter is received.

6. A method as described in claim 5, wherein the waveform representation of the preview is generated prior to applying the computed adjustments to the audio signal to generate the adjusted audio signal.

7. A method as described in claim 1, wherein the adjustments result in the loudness of at least one of the primary or secondary data being substantially leveled over the audio signal.

8. A method as described in claim 1, wherein the adjustments result in the loudness of at least one of the primary or secondary data being amplified over the audio signal.

9. A method as described in claim 8, wherein the increase of the target dynamic range parameter increases the desired difference between the loudness of the primary and secondary sound data, and the adjustments are configured to adjust the loudness of the portion to result in the primary and secondary sound data substantially having the increased desired difference in the loudness.

10. A method as described in claim 1, wherein the primary data corresponds to speech, the secondary data corresponds to background noise, and the target dynamic range parameter defines the desired difference between the loudness of the speech and the loudness of the background noise.

11. In a digital audio environment to adjust primary and secondary sound data originating as part of an audio signal and to display a preview of adjusted sound data by one or more computing devices, a method comprising:
generating a graphical user interface for display that includes:
a first waveform representation configured to represent an unadulterated version of the audio signal; and
a second waveform representation configured to represent an adjusted version of the audio signal that is adjustable based input received via one or more user interface elements; and
responsive to receiving input via one of the user interface elements to change a target dynamic range parameter that defines a desired difference in loudness between the primary and secondary sound data respectively, updating the second waveform representation to reflect adjustments to the loudness computed according to the input to change the target dynamic range parameter.

12. A method as described in claim 11, further comprising computing the adjustments to the loudness to result in the primary and secondary sound data having the desired difference in the loudness.

13. A method as described in claim 11, wherein the user interface element to adjust the target dynamic range parameter comprises a slider that enables the target dynamic range parameter to be increased or decreased.

14. A method as described in claim 11, wherein the one or more user interface elements include separate amplification and leveling user interface elements, the amplification user interface element enabling amplification adjustments to be made to the primary and secondary sound data, the leveling user interface element enabling leveling adjustments to be made to the primary and secondary sound data, and the input received via the one user interface element to adjust the target dynamic range parameter effective to make both the amplification and the leveling adjustments to the primary and secondary sound data independent of inputs received via the amplification and leveling user interface elements.

15. A method as described in claim 11, wherein the second waveform representation is updated for display in the user interface without generating the adjusted version of the audio signal.

16. A method as described in claim 11, further comprising:
receiving additional input via the one or more user interface elements to apply the computed adjustments to the audio signal; and
generating the adjusted version of the audio signal by adjusting the audio signal in accordance with the computed adjustments.

17. A method as described in claim 11, further comprising outputting the adjusted version of the audio signal via an audio output device.

18. A system implemented in a digital audio environment to adjust primary and secondary sound data originating as part of an audio signal, the system comprising:
a loudness adjustment module, implemented at least partially in hardware, to:
change a target dynamic range parameter that defines a desired difference between a loudness of the primary and the secondary sound data responsive to receiving input via a user interface to make the change; and
compute adjustments to the loudness for at least a portion of the audio signal responsive to receipt of the input and to result in the primary and secondary sound data substantially having the desired difference in the loudness; and
a display device to display via the user interface a preview of a new audio signal that reflects application of the computed loudness adjustments to the audio signal.

19. A system as described in claim 18, wherein the preview of the new audio signal comprises a waveform representation of the new audio signal.

20. A system as described in claim 18, wherein the preview of the new audio signal is updated for display substantially in real-time in conjunction with receiving the input to change the target dynamic range parameter.
